(19) United States
(12) Patent Application Publication
(10) Pub. No.: US 2008/0141082 A1
(43) Pub. Date: Jun. 12, 2008

(54) TEST MODE MULTI-BYTE PROGRAMMING WITH INTERNAL VERIFY AND POLLING FUNCTION

(75) Inventors: On-Pong Roderick Ho, Milpitas, CA (US); Dixie Nguyen, San Jose, CA (US); Dinu Patrascu, Sunnyvale, CA (US); Ivan N. Kutzarov, South Lanarkshire (GB); Graham H.M. Stout, Glasgow (GB)

Correspondence Address: SCHWEGMAN, LUNDBERG & WOESSNER / ATMEL, P.O. BOX 2938, MINNEAPOLIS, MN, 55402, US

(73) Assignee: Atmel Corporation, San Jose, CA (US)

(21) Appl. No.: 11/567,560

(22) Filed: Dec. 6, 2006

(51) Int. Cl. G11C 29/00

(52) U.S. Cl. 714/718

(57) ABSTRACT

A method, device, and processor-readable medium for testing semiconductor devices. A method for testing a semiconductor device comprises: a) entering a multi-byte programming mode; b) programming a plurality of bytes, each byte programmed with identical data; and c) verifying each programmed byte one byte at a time, returning to step b) if any byte fails to verify, otherwise waiting for a next command. A semiconductor device comprises a memory array and a peripheral circuit, the peripheral circuit including a controller configured to simultaneously program a selected plurality of bytes of the memory array with identical data when the multi-byte programming mode is selected, the program data circuit configured to be coupled to selected columns in the memory array corresponding to the selected plurality of bytes when the multi-byte programming mode is selected; and a sense amplifier configured to verify each byte of the selected plurality of bytes one byte at a time, the sense amplifier configured to be coupled to selected columns in the memory array corresponding to the selected byte to be verified. A processor-readable medium stores instructions that, when executed by a processor, perform steps of the method.

### TECHNICAL FIELD

This invention concerns testing of semiconductor devices, particularly testing using multi-byte programming.

### BACKGROUND INFORMATION

Semiconductor devices, including memory devices, are tested prior to their sale to determine whether the devices contain any defects. Testing may occur after wafer fabrication or after package assembly. During testing, the semiconductor device is attached to a test card (also known as a socket board or interface board) which in turn is connected to an external tester which tests the semiconductor devices.

Testing can have a major impact on the production costs of semiconductor devices. It is desirable to keep testing time as short as possible in order to keep production costs down. However, while more testing logic and testing functions may be built into a device in order to speed up testing time, these result in an overall larger die size when a smaller die size is usually preferred.

Multi-byte programming may also be used to decrease testing time. Current implementations of multi-byte programming employ external fixed time programming, since no minimum fixed time programming may be used given variation of different byte program characteristics within the die. Therefore, there is no way to determine that all the bytes were able to program correctly within a minimum fixed time.

It would be desirable to decrease testing time while not appreciably increasing the die size of a semiconductor device.

### SUMMARY OF THE INVENTION

One embodiment of the invention is a method for testing a device. The method comprises: a) entering a multi-byte programming mode; b) programming a plurality of bytes, each byte programmed with identical data; and c) verifying each programmed byte one byte at a time, returning to step b) if any byte fails to verify, otherwise waiting for a next command.

In another embodiment, a semiconductor device comprises a memory array and a peripheral circuit. The peripheral circuit includes: 1) a controller configured to select a multi-byte programming mode; 2) a program data circuit configured to simultaneously program a selected plurality of bytes of the memory array with identical data when the multi-byte programming mode is selected, the program data circuit configured to be coupled to selected columns in the memory array corresponding to the selected plurality of bytes when the multi-byte programming mode is selected; and 3) a set of sense amplifier configured to verify each byte of the plurality of bytes one byte at a time, the sense amplifier configured to be coupled to selected columns in the memory array corresponding to the selected byte to be verified.

In yet another embodiment, a processor-readable medium stores instructions that, when executed by a processor, perform steps of a method. The method comprises: a) entering a multi-byte programming mode; b) programming a plurality of bytes, each byte programmed with identical data; and c) verifying each programmed byte one byte at a time, returning to step b) if any byte fails to verify, otherwise waiting for a next command.

### BRIEF DESCRIPTION OF THE DRAWINGS

FIG. 1 is a block diagram of an exemplary testing environment in accord with the present invention.

FIG. 2 is a block diagram of an exemplary embodiment of a peripheral circuit.

FIG. 3 is a flowchart of an exemplary method for testing a device in accord with the present invention.

FIG. 4 is a block diagram of an exemplary embodiment of a Y decoder in the peripheral circuit shown in FIG. 2.

### DETAILED DESCRIPTION OF THE INVENTION

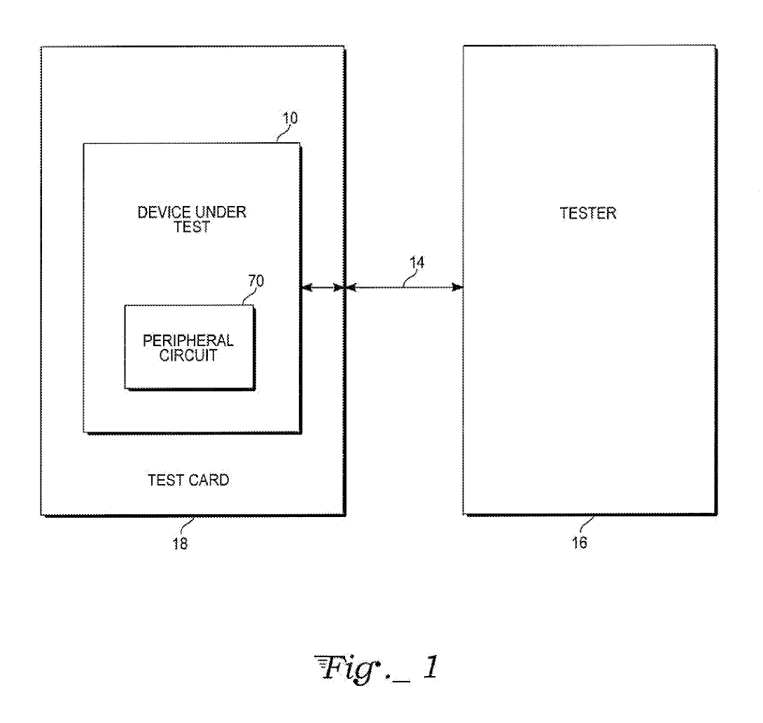

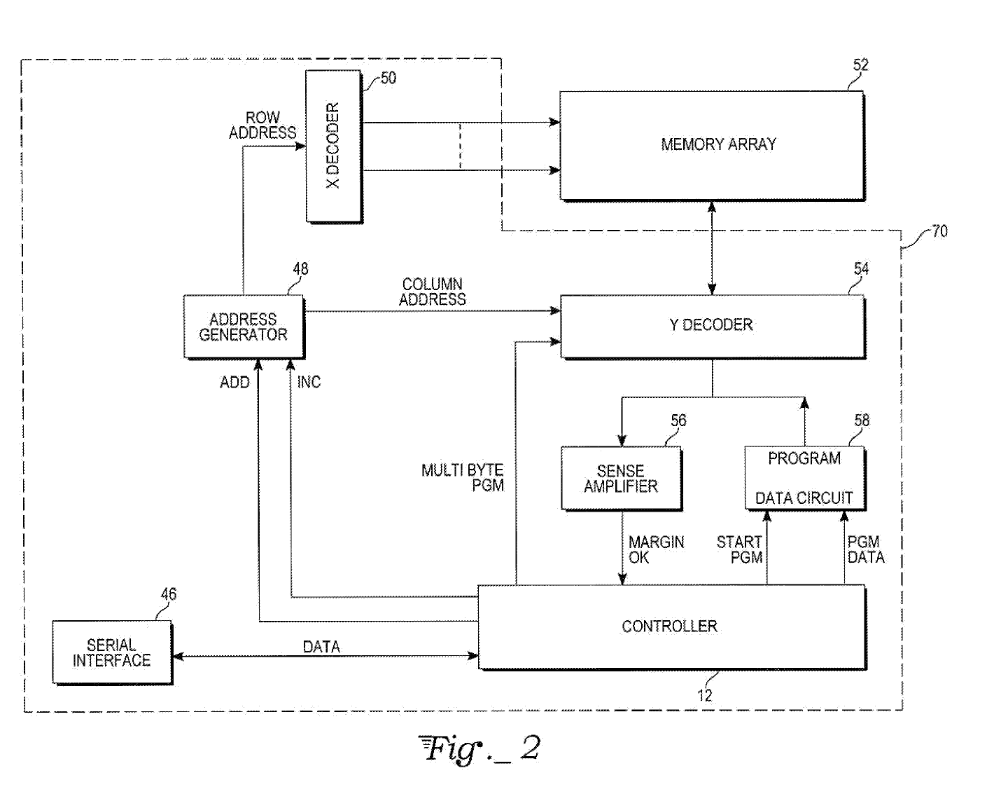

An exemplary configuration of a testing environment is shown in FIG. 1. The device under test 10, a semiconductor device (for example, a memory device) in wafer or package form, includes a peripheral circuit 70 that can be used for testing. It should be appreciated the peripheral circuit 70 contains circuitry that can perform a multitude of functions as required by the semiconductor device, including those for testing. The details of the peripheral circuit 70 will be described further in connection with FIG. 2. The device under test 10 is attached to a test card 18, or socket board (not shown). The test card 18 is coupled to a tester 16 by a bus 14, thereby coupling the test card 18 and the device under test 10. An interface (not shown) between the tester 16 and the device under test 10 is also provided. Any tester known to those of skill in the art may be used in this invention. In addition, other testing environments may be employed in other embodiments.

The cells in the memory array of the device under test are programmed with test data prior to a verification procedure. Programmed bytes are verified during the testing procedure. Verification includes determining whether the programming margin is acceptable. An acceptable programming margin is obtained when more electrical charge is stored in a cell's floating gate than is required to turn the cell off (i.e., logical 0) but the amount of charge stored does not overstress or otherwise damage the cell. If the programming margin is not acceptable, charge may be lost, causing the cell to become erased.

In FIG. 2, one exemplary embodiment of the device under test's peripheral circuit 70 includes a controller 12. The controller 12 is coupled to a serial interface 46 (which in this embodiment is an interface with the tester) as well as a single set of sense amplifiers 56 used to read each byte of data under test and verify the programming margin of each byte, and a program data circuit 58. (In other embodiments, the controller may be a processor, microprocessor, etc.) The controller 12 exchanges data with the serial interface 46. The program data circuit 58 receives signals from the controller 12 indicating when to start programming data as well as the data to be programmed. A Y decoder 54 is also coupled to the controller 12, the sense amplifier 56, the program data circuit 58, and the device's memory array 52. An address generator 48 is coupled to both the X decoder 50 and Y decoder 54. The address generator 48 generates row addresses to be sent to the X decoder 50 and column addresses to be sent to the Y decoder 54. The address generator 48 receives signals from the controller 12, one signal indicating an address and another signal indicating when to increment the address. The controller 12 selects the multi-byte program mode and also sends a signal to the Y decoder 54 to indicate when the multi-byte program mode has been selected. A power supply (not shown) is required for programming; the power supply may be located on the device or may be external to the device. Other embodiments of the peripheral circuit may feature different configurations.

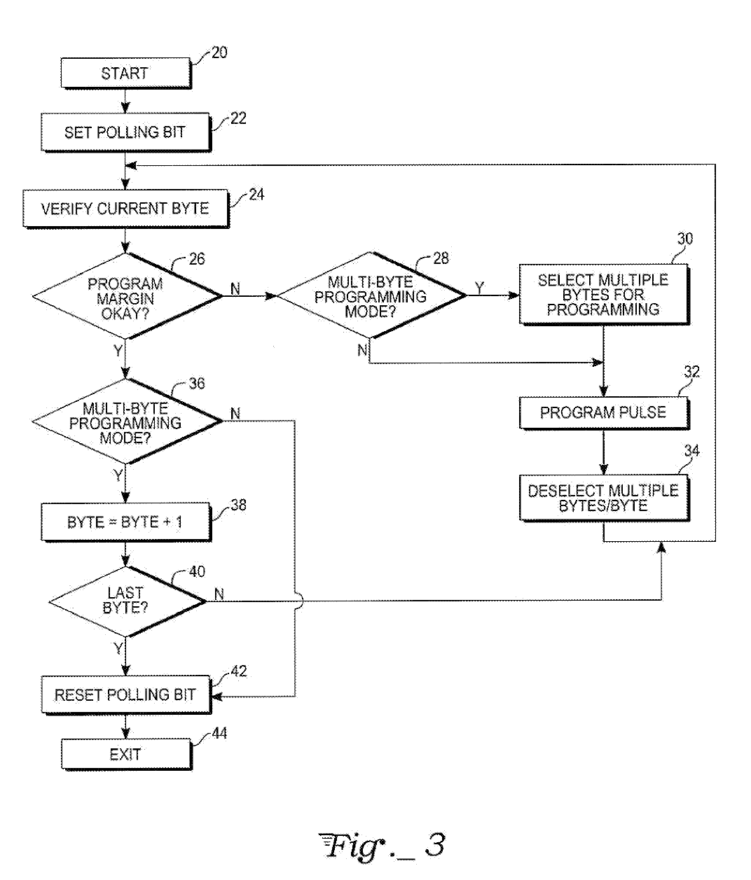

With regard to FIG. 3, one embodiment of the verification procedure begins (block 20) with the peripheral circuit's controller setting a polling bit (block 22) to indicate the verification process is in progress. The current byte (starting with a first byte to be programmed) is verified (block 24), including determining whether the programming margin is acceptable (block 26). If the programming margin is acceptable (block 26), and if multi-byte programming mode has been selected (block 36), the address counter increments one byte (block 38). (In one embodiment, the multi-byte programming mode is accessed using a sequence specific to the device under test; other access methods may be used in other embodiments. When the multi-byte programming mode is entered, an address counter is reset. In one embodiment, the address counter is reset to the initial address of the multiple bytes to be programmed.) Provided the byte previously verified was not the last byte to be verified (block 40), the verification process continues (block 24). However, if the byte previously verified was the last byte to be verified (block 40), the polling bit is reset (42), indicating that the multi-byte programming with verify process is finished (block 44). If multi-byte programming mode has not been selected (block 36), regular byte programming is performed, and the polling bit is reset (42) by the controller, indicating that the verification process is finished (block 44).

If the programming margin is not acceptable (block 26), and if the multi-byte programming mode has been selected (block 28), the controller will generate a signal to turn on multiple columns in the memory array during a programming phase, i.e., multiple bytes will be selected for programming (block 30). The selected columns are then simultaneously programmed with the same data using a program pulse (block 32). The selected columns, corresponding to the selected bytes, are deselected following the programming pulse (block 34). If the multi-byte programming mode has not been selected (block 28), regular byte programming is performed, and the byte that failed to verify is programmed with a program pulse (block 32) and is then deselected (block 34).

Following the programming operation, the first byte in the plurality of programmed bytes is verified (block 24). If the programming margin is acceptable (block 26), and if multi-byte programming mode has been selected (block 36), the address counter increments one byte (block 38). Provided the byte previously verified was not the last byte to be verified (block 40), the verification process continues (block 24). However, if the byte previously verified was the last byte to be verified (block 40), the polling bit is reset (42), indicating that the multi-byte programming with internal verify process is finished (block 44).

In multi-byte programming mode, if the current byte fails to verify due to programming margin (block 26), all the bytes under test loop back to the multi-byte programming phase again (block 28 et seq.).

Parameters for testing may be set externally. These parameters include, but are not limited to, the number of bytes under programming, and the maximum number of attempts to program a byte. In some embodiments, the strength of programming could be increased if bytes continue to fail to verify.

Using the multi-byte programming mode discussed above, the entire memory array can be programmed and verified as fast as the internal time clock of the device under test permits. In multi-byte programming mode, 2^{p} selected columns in each I/O circuit are programmed, where p is an integer.

Code segments for implementing the multi-byte programming method may be implemented in hardware, software, firmware or a combination thereof. The code segments may be stored and executed by either a processor associated with the device under test or a processor associated with the tester. (The term “processor” should be understood to encompass a microcontroller, controller microprocessor, processor, etc.) The program or code segments can be stored in a processor-readable medium or transmitted by a computer data signal embodied in a carrier wave over a transmission medium or communication link. The processor-readable medium may include any medium that can store or transfer information, such as instructions which, when executed by a processor, perform steps of a method. Examples of the processor-readable medium include an electronic circuit, a semiconductor memory device, a ROM, a flash memory, an erasable ROM (EROM), a floppy diskette, a CD-ROM, an optical disk, a hard disk, a fiber optic medium, a radio frequency (RF) link, etc. The computer data signal may include any signal that can propagate over a transmission medium such as electronic network channels, optical fibers, air, electromagnetic, RF links, etc. The code segments may be downloaded via computer networks such as the Internet, Intranet, etc.

In one exemplary embodiment, a hardwired controller implements multi-byte programming. In this embodiment, the code segments are translated into the internal logic. In another exemplary embodiment, a microcontroller implements multi-byte programming. In this embodiment, the code segments could be either translated into the internal logic or downloaded externally via the tester.

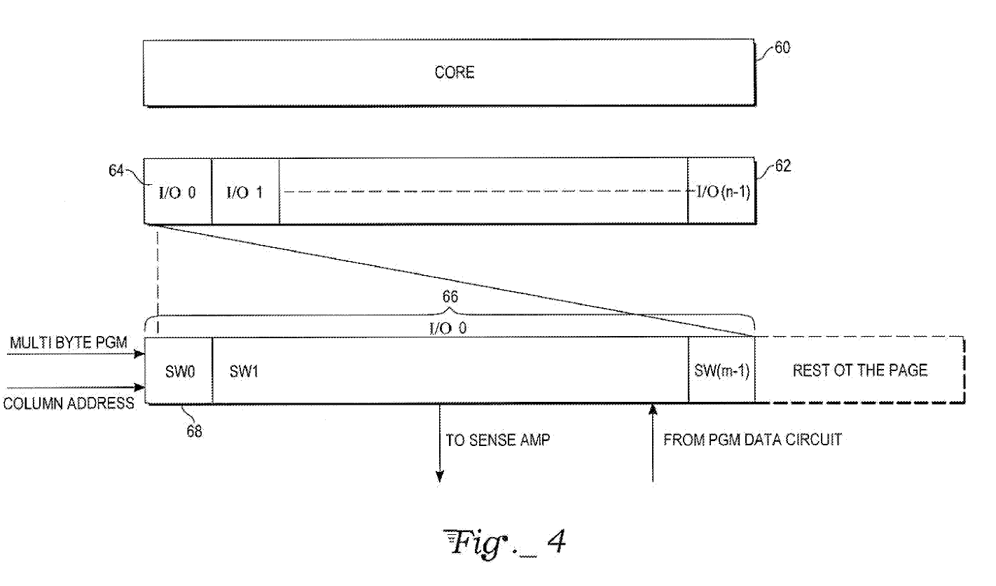

In FIG. 4, an exemplary embodiment of the Y decoder and memory array discussed above in FIG. 2 is shown. In FIG. 2, the memory array core 52 is coupled to the sense amplifier 56 and program data circuit 58 via the Y decoder 54. Returning to FIG. 4, the Y decoder is organized as n bit Y decoders, or I/O circuits 62 I/O-I/O₍ₙ₋₁₎, where n is the number of bits per byte. One exemplary I/O circuit, I/O 64, like the other I/O circuits, includes a plurality of switches 66 SW-SWm−1, where m is the number of bytes of a page. SW 68, like the other switches 66, couples the corresponding column in the memory core 60 to one sense amplifier during the verify phase or to the program data circuit during the programming phase. For each I/O during multi-byte programming, a plurality of switches are on, while during verify only one switch is on at any given time. The specific design of the Y decoder depends on the design of the memory array core 60.

The above description is illustrative and not restrictive. Variations of the invention will be apparent to those of skill in the art. The scope of the invention should therefore be determined not by reference to the above description but instead with reference to the appended claims.

What is claimed is:

1. A method for testing a device, the method comprising:
a) entering a multi-byte programming mode;
b) programming a plurality of bytes, each byte programmed with identical data;
c) verifying each programmed byte one byte at a time, returning to step b) if any byte fails to verify, otherwise waiting for a next command.

2. The method of claim 1 wherein verifying each programmed byte includes determining whether a programming margin is acceptable.

3. The method of claim 1 further comprising tracking each byte that has been verified.

4. The method of claim 1 further comprising setting a polling bit.

5. The method of claim 4 further comprising resetting the polling bit after verifying all programmed byte.

6. The method of claim 1 wherein each byte of the plurality of bytes is programmed simultaneously with each other of the plurality of bytes being programmed.

7. The method of claim 1 further comprising resetting an address counter.

8. The method of claim 7 wherein the address counter is reset to an initial address of one of the plurality of bytes to be programmed.

9. A semiconductor device comprising:
a) a memory array; and
b) a peripheral circuit, the peripheral circuit including:
i) a controller configured to select a multi-byte programming mode;
ii) a program data circuit configured to simultaneously program a selected plurality of bytes of the memory array with identical data when the multi-byte programming mode is selected, the program data circuit configured to be coupled to selected columns in the memory array corresponding to the selected plurality of bytes when the multi-byte programming mode is selected; and
iii) a sense amplifier configured to verify each byte of the selected plurality of bytes one byte at a time, the sense amplifier configured to be coupled to selected columns in the memory array corresponding to the selected byte to be verified.

10. The semiconductor device of claim 9 wherein the peripheral circuit further includes a Y decoder configured to turn on the selected columns in a memory array during a multi-byte programming operation.

11. The semiconductor device of claim 9 wherein the peripheral circuit further includes a Y decoder configured to select one byte at a time during a verification process.

12. The semiconductor device of claim 9 wherein the controller is further configured to signal an end of a verification process.

13. The semiconductor device of claim 9 wherein the peripheral circuit further includes an address generator configured to track each byte that has been verified.

14. The semiconductor device of claim 9 further comprising an interface to a tester.

15. The semiconductor device of claim 9 further comprising a means for coupling the semiconductor device to a tester.

16. The semiconductor device of claim 10 wherein the Y decoder further comprises a plurality of I/O circuits.

17. The semiconductor device of claim 16 wherein each I/O circuit includes a plurality of switches.

18. A processor-readable medium storing instructions that, when executed by a processor, perform steps of a method, the method comprising:
a) entering a multi-byte programming mode;
b) programming a plurality of bytes, each byte programmed with identical data;
c) verifying each programmed byte one byte at a time, returning to step b) if any byte fails to verify.

19. The processor-readable medium of claim 18 wherein verifying each programmed byte includes determining whether a programming margin is acceptable.

20. The processor-readable medium of claim 18, the method further comprising tracking each byte that has been verified.

21. The processor-readable medium of claim 18, the method further comprising setting a polling bit.

22. The processor-readable medium of claim 21, the method further comprising resetting the polling bit after verifying each programmed byte.

23. The processor-readable medium of claim 18 wherein each byte of the plurality of bytes is programmed simultaneously.

24. The processor-readable medium of claim 18, the method further comprising resetting an address counter.

25. The processor-readable medium of claim 24 wherein the address counter is reset to an initial address of one of the plurality of bytes to be programmed.
